(19) United States
(12) Patent Application Publication
(10) Pub. No.: US 2026/0075847 A1
(43) Pub. Date: Mar. 12, 2026

(54) STACKED SUBSTRATE AND METHOD OF MANUFACTURING SEMICONDUCTOR DEVICE

(71) Applicant: Kioxia Corporation, Tokyo (JP)

(72) Inventor: Yoshio MIZUTA, Yokkaichi Mie (JP)

(73) Assignee: Kioxia Corporation, Tokyo (JP)

(21) Appl. No.: 19/074,153

(22) Filed: Mar. 7, 2025

(30) Foreign Application Priority Data
Sep. 12, 2024 (JP) 2024-158226

(51) Int. Cl. H10B 80/00; H01L 23/00; H01L 25/00; H01L 25/065; H01L 25/18

(52) U.S. Cl. CPC H10B 80/00; H10W 90/00; H10W 80/211; H10W 80/312; H10W 80/327; H10W 90/792

(57) ABSTRACT

A stacked substrate according to an embodiment is a stacked substrate for separating using thermal expansion by laser light, and includes: a semiconductor substrate; a first insulating layer disposed above the semiconductor substrate; a first polysilicon layer that is disposed on the first insulating layer in contact with the first insulating layer, and doped with phosphorus; and a second polysilicon layer that extends in the first insulating layer, directly connects the first polysilicon layer and the semiconductor substrate, and is doped with phosphorus.

### CROSS-REFERENCE TO RELATED APPLICATIONS

This application is based upon and claims the benefit of priority from Japanese Patent Application No. 2024-158226, filed on Sep. 12, 2024; the entire contents of which are incorporated herein by reference.

### FIELD

Embodiments described herein relate generally to a stacked substrate and a method of manufacturing a semiconductor device.

### BACKGROUND

A semiconductor device such as a three-dimensional nonvolatile memory may be manufactured by bonding a support substrate on which a plurality of memory pillars are formed and a semiconductor substrate on which a peripheral circuit is formed. After the bonding to the semiconductor substrate, the support substrate is separated and reused.

An insulating layer or the like for protecting the support substrate is formed on the support substrate, and the support substrate on the insulating layer side is thermally expanded by irradiation with laser light or the like. As a result, the support substrate and the insulating layer can be cleaved to separate the support substrate. At this time, damage such as lattice defects may occur in the support substrate.

### BRIEF DESCRIPTION OF THE DRAWINGS

FIG. 1 is a cross-sectional view illustrating a configuration example of a semiconductor device according to an embodiment;

FIGS. 2A to 2C are cross-sectional views sequentially illustrating a part of the procedure of the method of manufacturing the semiconductor device according to the embodiment;

FIGS. 3A to 3C are diagrams sequentially illustrating a part of the procedure of the method of manufacturing the semiconductor device according to the embodiment;

FIGS. 4A and 4B are diagrams sequentially illustrating a part of the procedure of the method of manufacturing the semiconductor device according to the embodiment;

FIG. 5 is a diagram illustrating a part of the procedure of the method of manufacturing the semiconductor device according to the embodiment;

FIGS. 6A to 6C are diagrams sequentially illustrating a part of the procedure of the method of manufacturing the semiconductor device according to the embodiment;

FIGS. 7A to 7E are diagrams sequentially illustrating a part of the procedure of the method of manufacturing the semiconductor device according to the embodiment;

FIG. 8 is a diagram sequentially illustrating a part of the procedure of the method of manufacturing the semiconductor device according to the embodiment;

FIGS. 9A to 9E are cross-sectional views illustrating a part of a procedure of regeneration processing of the support substrate according to the embodiment;

FIGS. 10A to 10C are cross-sectional views illustrating a part of a procedure of regeneration processing of the support substrate according to the embodiment;

FIG. 11 is a cross-sectional view illustrating an example of a configuration of a support substrate according to a modification of the embodiment;

FIGS. 12A to 12E are cross-sectional views schematically illustrating an example of a state in which a support substrate according to the modification of the embodiment is separated;

FIGS. 13A to 13E are cross-sectional views schematically illustrating another example of a state in which the support substrate according to the modification of the embodiment is separated;

FIG. 14 is a diagram schematically illustrating a measurement substrate and a method of measuring an absorption rate according to an example;

FIG. 15 is a diagram schematically illustrating a method of calculating the absorption rate of a polysilicon layer in the measurement substrate according to the example;

FIG. 16 is a diagram schematically illustrating the method of calculating the absorption rate of a polysilicon layer in the measurement substrate according to the example; and

FIG. 17 is a graph illustrating an absorption rate of a polysilicon layer in the measurement substrate according to the example.

### DETAILED DESCRIPTION

A stacked substrate according to an embodiment is a stacked substrate for separating using thermal expansion by laser light, and includes a semiconductor substrate, a first insulating layer that is disposed above the semiconductor substrate, a first polysilicon layer that is disposed on the first insulating layer in contact with the first insulating layer, and doped with phosphorus, and a second polysilicon layer that extends in the first insulating layer, directly connects the first polysilicon layer and the semiconductor substrate, and is doped with phosphorus.

Hereinafter, embodiments of the present invention are described in detail with reference to the drawings. Note that the present invention is not limited by the following embodiments. In addition, components in the following embodiments include those that can be easily assumed by those skilled in the art or those that are substantially the same.

### Configuration Example of Semiconductor Device

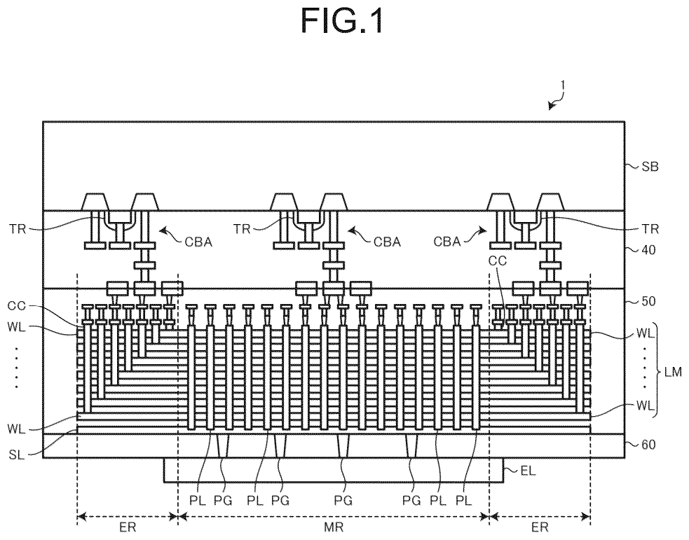

FIG. 1 is a cross-sectional view illustrating a configuration example of a semiconductor device 1 according to an embodiment. However, in FIG. 1, hatching is omitted in consideration of visibility of the drawing.

As illustrated in FIG. 1, the semiconductor device 1 includes an electrode film EL, a source line SL, and a stacked body LM obtained by stacking a plurality of word lines WL in an order from the lower side of the drawing. In addition, the semiconductor device 1 includes a peripheral circuit CBA provided on a semiconductor substrate SB above the stacked body LM.

The source line SL is disposed on the electrode film EL via an insulating layer 60. The source line SL is, for example, a polysilicon layer.

A plurality of plugs PG are arranged in the insulating layer 60, and the source line SL and the electrode film EL maintain electrical conduction via the plugs PG. As a result, a source potential can be applied to the source line SL from the outside of the semiconductor device 1 via the electrode film EL and the plug PG.

The stacked body LM obtained by stacking the plurality of word lines WL is disposed on the source line SL. A memory region MR is disposed in a central portion of the stacked body LM, and contact regions ER are arranged in both end portions of the stacked body LM.

In the memory region MR, pillars PL are arranged as a plurality of memory pillars penetrating the word line WL in the stacking direction. A plurality of memory cells are formed at intersections of the pillars PL and the word lines WL. As a result, the semiconductor device 1 is configured as, for example, a three-dimensional nonvolatile memory in which memory cells are three-dimensionally arranged in the memory region MR.

In the contact region ER, a plurality of contacts CC respectively connected to the plurality of word lines WL are arranged. Note that in the present specification, in the extending direction of the contact CC, the connection end side of the contact CC with the word line WL is defined as the lower side of the semiconductor device 1.

From the contact CC, a write voltage, a read voltage, and the like are applied to a memory cell in the memory region MR in the central portion of the stacked body LM via the word line WL at the same height position as the memory cell. In this manner, the word lines WL stacked in multiple layers are individually drawn out by these contacts CC.

The plurality of word lines WL, the pillars PL, and the contacts CC are covered with an insulating layer 50. The insulating layer 50 also extends around the plurality of word lines WL.

The semiconductor substrate SB above the insulating layer 50 is, for example, a silicon substrate. The peripheral circuit CBA including a transistor TR, wiring, and the like is disposed on the surface of the semiconductor substrate SB. Various voltages applied from the contacts CC to the memory cells are controlled by peripheral circuits CBA electrically connected to the contacts CC. In this manner, the peripheral circuit CBA controls the electrical operation of the memory cell.

The peripheral circuit CBA is covered with the insulating layer 40, and the insulating layer 40 and the insulating layer 50 covering the stacked body LM are bonded to each other, thereby forming and thus the semiconductor device 1 including the configuration of the plurality of word lines WL, pillars PL, contacts CC, and the like, and the peripheral circuit CBA.

### Method of Manufacturing Semiconductor Device

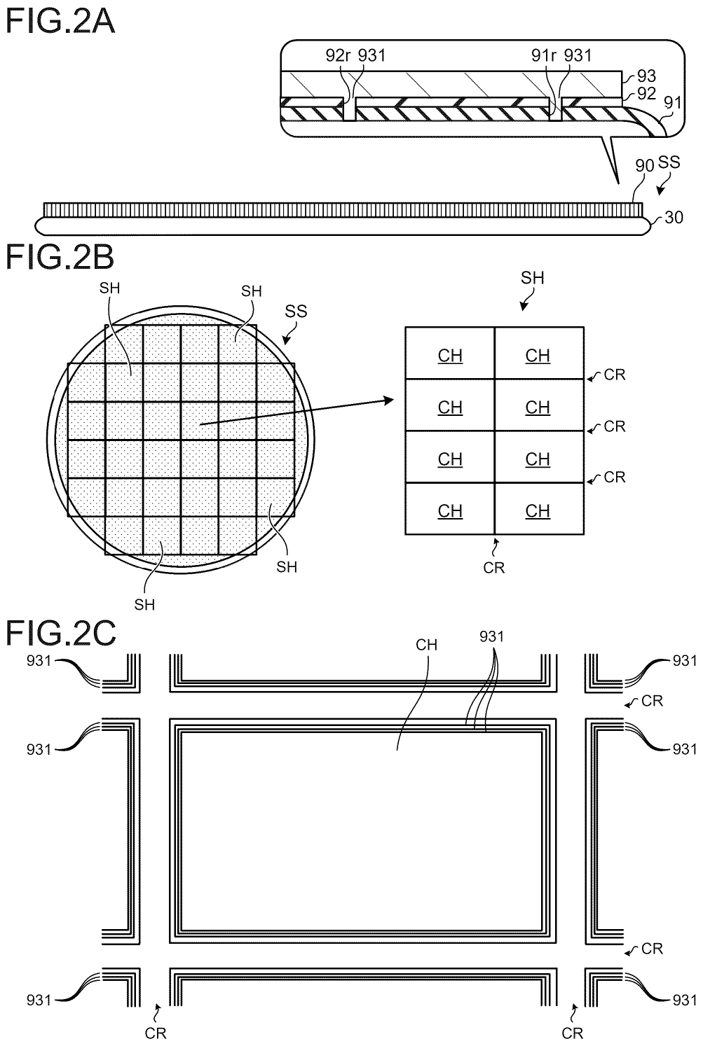

Next, a method of manufacturing the semiconductor device 1 according to the embodiment is described with reference to FIGS. 2A to 10C. The method of manufacturing the semiconductor device 1 may partially include a method of manufacturing a support substrate SS, a method of separating the support substrate SS, and a method of regenerating the support substrate SS.

FIGS. 2A to 9E are diagrams sequentially illustrating a part of the procedure of the method of manufacturing the semiconductor device 1 according to the embodiment. FIGS. 2A to 9E are cross-sectional views of the semiconductor device 1 in the middle of the manufacturing unless otherwise specified.

As illustrated in FIG. 2A, a semiconductor substrate 30 such as a silicon substrate is prepared. After both surfaces of the semiconductor substrate 30 are cleaned, an insulating layer 91 such as a silicon nitride layer is formed.

The insulating layer 91 is formed on both surfaces of the semiconductor substrate 30 with a thickness of 50 nm or more and 100 nm or less, for example, 70 nm, for example, by using chemical vapor deposition (CVD) or the like. However, as described below, in the embodiment, damage to the semiconductor substrate 30 in a step of separating the support substrate SS described below is prevented. Therefore, the insulating layer 91 used for surface protection may not be formed.

Furthermore, for example, an insulating layer 92 such as a silicon oxide layer is formed with a layer thickness of, for example, 20 nm or more and 50 nm or less on the semiconductor substrate 30 covered with the insulating layer 91. The insulating layer 92 functions as a heat insulating layer that insulates the semiconductor substrate 30 from heat of a polysilicon layer 93 serving as a heat source in the step of separating the support substrate SS described below.

In addition, a plurality of recesses 92r and 91r respectively penetrating the insulating layers 92 and 91 and having a predetermined pattern are formed. As a result, the semiconductor substrate 30 is exposed from the bottom surfaces of the recesses 92r and 91r. In addition, the polysilicon layer 93 filled in the recesses 92r and 91r and covering the upper surface of the insulating layer 92 is further formed. As a result, the polysilicon layer 93 has a protrusion 931 that penetrates the insulating layers 92 and 91 and reaches the semiconductor substrate 30.

The main body portion of the polysilicon layer 93 on the upper surface of the insulating layer 92 is formed to be thicker than the insulating layer 92 and has a layer thickness of, for example, 100 nm or more and 300 nm or less. In addition, the polysilicon layer 93 is doped with phosphorus. By doping the polysilicon layer 93 with phosphorus, the absorption rate of light with a wavelength of 9 μm or more and 10 μm or less can be increased, and the polysilicon layer 93 can be thermally expanded to cleave the insulating layer 92 and the polysilicon layer 93 in the step of separating the support substrate SS described below.

The phosphorus concentration of the polysilicon layer 93 is, for example, 1.5×10²⁰ atom/cm³ or more and is more preferably 3.0×10²⁰ atom/cm³ or more. As a result, in the non-doped polysilicon layer, the absorption rate of light with a wavelength of 9 μm or more and 10 μm or less is 0%, and in the polysilicon layer 93 having a phosphorus concentration, the absorption rate can be increased to, for example, 50% or more and more preferably 75%.

As a result, the polysilicon layer 93 can be caused to generate heat with the light of the above-described wavelength and thermally expanded. The thermal conductivity of the polysilicon layer 93 is 10 times or more the thermal conductivity of the insulating layer 92 such as a silicon oxide layer. In addition, when the thermal conductivity of each layer of the support substrate SS is compared, the thermal conductivity of the insulating layer 91 which is a silicon nitride layer or the like and the thermal conductivity of the semiconductor substrate 30 which is a silicon substrate or the like are respectively 10 times or more the insulating layer 92 which is a silicon oxide layer or the like.

At this time, the protrusion 931 of the polysilicon layer 93 can be doped with phosphorus at the same concentration as the main body portion of the polysilicon layer 93 and more preferably phosphorus at a lower concentration than the main body portion of the polysilicon layer 93. At this time, the phosphorus concentration is adjusted so as to be maintained to such an extent that the conductivity of the protrusion 931 is not impaired.

A method of adjusting the phosphorus concentration of the polysilicon layer 93 is described in more detail. When the source gas of the polysilicon layer 93 is supplied to the insulating layer 92, filling of the recess 92r of the insulating layer 92 with the polysilicon layer 93 and formation of the polysilicon layer 93 on the upper surface of the insulating layer 92 proceed in parallel.

When the phosphorus concentration of the protrusion 931 is equal to that of the main body portion of the polysilicon layer 93, while the phosphorus concentration mixed in the source gas of the polysilicon layer 93 is constantly maintained, the filling of the recesses 91r and 92r with the polysilicon layer 93 and the formation of the polysilicon layer 93 on the upper surface of the insulating layer 92 can be continuously performed.

When the phosphorus concentration of the protrusion 931 is lower than that of the main body portion of the polysilicon layer 93, the recesses 91r and 92r are filled with the polysilicon layer, the protrusion 931 is formed, then the polysilicon layer having a low phosphorus concentration on the upper surface of the insulating layer 92 is removed, and then the polysilicon layer 93 doped with a predetermined phosphorus concentration is formed again on the insulating layer 92.

As a result, the polysilicon layer 93 including the protrusion 931 doped with phosphorus at a predetermined concentration is formed, and the main body portion of the polysilicon layer 93 on the upper surface of the insulating layer 92 is electrically connected to the semiconductor substrate 30 by the protrusion 931 penetrating the insulating layers 92 and 91.

In addition, as described above, the support substrate SS in which a multilayer structure body 90 including the insulating layers 91 and 92 and the polysilicon layer 93 is formed on the semiconductor substrate 30 is manufactured. As described above, the support substrate SS is configured with a stacked substrate in which a plurality of layers are formed on the semiconductor substrate 30.

Note that the main body portion of the polysilicon layer 93 covering the upper surface of the insulating layer 92 is an example of a first polysilicon layer, and the protrusion 931 electrically connecting the main body portion of the polysilicon layer 93 and the semiconductor substrate 30 is an example of a second polysilicon layer.

Here, the pattern of the protrusion 931 of the polysilicon layer 93 is described in more detail using the schematic layout diagrams of FIGS. 2B and 2C.

FIG. 2B is a top view schematically illustrating a shot region SH and a chip region CH in the support substrate SS by forming the semiconductor device 1 on the support substrate SS later. As illustrated in FIG. 2B, the plurality of shot regions SH each have, for example, a rectangular shape and are arranged in a grid shape on the support substrate SS.

These shot regions SH become processing units in at least a part of step in a step of manufacturing the semiconductor device 1 described below. As an example, exposure using a lithography technique, transfer of a pattern using an imprint technique, and the like are performed for each shot region SH.

The individual shot region SH includes one or more chip regions CH. In the example of FIG. 2B, the number of chip regions CH in one shot region SH is eight. The individual chip region CH includes one semiconductor device 1. In the final stage of the step of manufacturing the semiconductor device 1, the chip region CH is cut into individual chips, and the singulated semiconductor device 1 is manufactured.

These chip regions CH are separated from each other by a kerf region CR. The kerf region CR is a portion cut by a dicing saw when the individual chip region CH is singulated. When the chip region CH is singulated, a part or all of the kerf region CR disappears.

FIG. 2C is a top view schematically illustrating a pattern of the protrusion 931 of the polysilicon layer 93. As illustrated in FIG. 2C, the protrusion 931 of the polysilicon layer 93 is provided at a position overlapping the individual chip region CH in the vertical direction.

More specifically, the protrusion 931 is disposed such that the positional relationship with the chip region CH in the vertical direction is along the outer edge portion of the chip region CH in the individual chip region CH. Therefore, for example, similarly to the chip region CH, the protrusion 931 is provided in a rectangular shape and is provided so as to surround the central portion of the chip region CH in a top view.

One or more rectangular protrusions 931 may be provided in one chip region CH. In the example of FIG. 2C, three protrusions 931 are provided in one chip region CH. That is, the protrusion 931 illustrated in FIG. 2C surrounds the central portion of the chip region CH in a triple manner in a top view.

Thereafter, a part of the semiconductor device 1 is formed on the support substrate SS configured as described above.

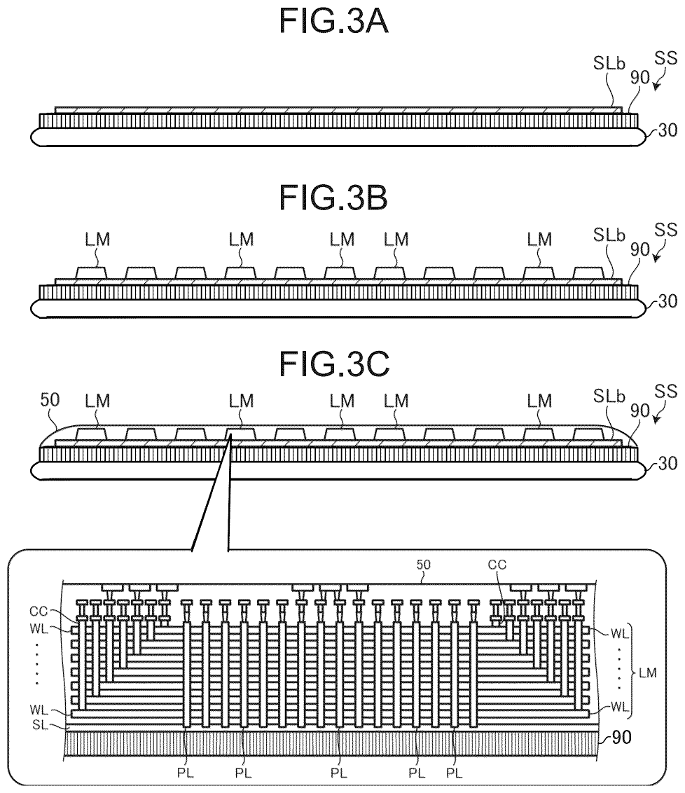

As illustrated in FIG. 3A, a conductive layer SLb is formed on the multilayer structure body 90 of the support substrate SS. The conductive layer SLb is, for example, a polysilicon layer and then becomes the source line SL of the semiconductor device 1. However, when the conductive layer SLb is formed on the multilayer structure body 90, the conductive layer SLb may be formed via another layer such as a silicon oxide layer or a polysilicon layer. The layer interposed between the multilayer structure body 90 and the conductive layer SLb may be a single-layer structure, a multilayer structure of layers of the same type, a multilayer structure of layers of different types, or the like.

As illustrated in FIG. 3B, the plurality of stacked bodies LM in which the plurality of word lines WL are stacked apart from each other are formed on the conductive layer SLb. As illustrated in the enlarged cross-sectional view of FIG. 3C, the plurality of pillars PL, the plurality of contacts CC, and the like are formed in the individually stacked body LM.

The stacked body LM in which the pillars PL, the contacts CC, and the like are formed is formed as follows. That is, a stacked body in which a plurality of silicon nitride layers and a plurality of silicon oxide layers are alternately stacked layer by layer is formed on the conductive layer SLb formed on the support substrate SS.

In addition, a plurality of contact holes reaching individual silicon nitride layers are formed in a partial region of the stacked body. In addition, a memory hole penetrating the stacked body and reaching the conductive layer SLb is formed, and the memory hole is filled with a memory layer, a semiconductor layer, and the like. At this time, the memory layer on the side surface of the semiconductor layer is partially removed to electrically connect the semiconductor layer and the conductive layer SLb.

Thereafter, the word lines WL are formed by replacing the plurality of silicon nitride layers of the stacked body with conductive layers by processing called replacement processing. In addition, the plurality of contact holes are filled with a conductive layer or the like to form the contact CC, and upper layer wiring or the like is formed on the stacked body LM.

As illustrated in FIG. 3C, the insulating layer 50 covering the plurality of stacked bodies LM in which the plurality of pillars PL, the plurality of contacts CC, and the like are formed as described above is formed. Electrode pads electrically connected to the pillars PL, the contacts CC, and the like of the stacked body LM are formed on the surface of the insulating layer 50.

Note that the insulating layer 50 including the plurality of stacked bodies LM in which the plurality of pillars PL and the like are formed is an example of a device layer including at least a part of the configuration of the semiconductor device 1.

Here, each processing illustrated in FIGS. 3A to 3C includes formation of various types of layers using a plasma-enhanced chemical vapor deposition (PECVD) method or the like, exposure development using a lithography technology, pattern transfer using an imprint technology, processing of each layer by reactive ion etching (RIE) or the like, and the like. At this time, for example, in plasma processing by PECVD, RIE, or the like, the insulating layer 50 or the like, which is a device layer, is charged, and arcing may occur.

As described above, the support substrate SS of the embodiment has the protrusion 931 that electrically connects the main body portion of the polysilicon layer 93 and the semiconductor substrate 30. As a result, the electricity accumulated in the insulating layer 50 can be released to the semiconductor substrate 30 side, and arcing can be prevented.

At this time, as described above, the protrusion 931 is formed so as to surround the individual chip region CH (see FIG. 2C) in a top view, and thus it is possible to more reliably prevent the influence of arcing on the semiconductor device 1 disposed in the chip region CH in the middle of manufacturing. In addition, as described above, the protrusion 931 is formed so as to surround the chip region CH in a multiple manner, and thus the influence of arcing on the semiconductor device 1 is further prevented.

However, as described above, one protrusion 931 may be provided in one chip region CH, that is, the protrusion 931 may surround the chip region CH in a single manner.

As illustrated in FIG. 4A, the plurality of peripheral circuits CBA including the transistors TR are formed on a semiconductor substrate SB separate from the support substrate SS. The plurality of peripheral circuits CBA are formed so as to correspond to, for example, the plurality of stacked bodies LM, respectively. In addition, the insulating layer 40 covering the peripheral circuit CBA is formed. An electrode pad electrically connected to the transistor TR and the like of the peripheral circuit CBA is formed on the surface of the insulating layer 40.

As illustrated in FIG. 4B, the surface of the support substrate SS on which the stacked body LM and the like are formed faces the surface of the semiconductor substrate SB on which the peripheral circuit CBA and the like are formed, the insulating layer 50 on the support substrate SS side and the insulating layer 40 on the semiconductor substrate SB side are bonded, and the support substrate SS and the semiconductor substrate SB are bonded.

These insulating layers 50 and 40 can be bonded by, for example, activating the surfaces thereof in advance by a plasma treatment or the like. In addition, when the insulating layers 50 and 40 are bonded, the support substrate SS and the semiconductor substrate SB are aligned so that the electrode pad formed on the insulating layer 50 and the electrode pad formed on the insulating layer 40 overlap each other.

After the insulating layers 50 and 40 are bonded, an annealing treatment is performed to bond both electrode pads, for example, by Cu-Cu bonding. As a result, the stacked body LM and the peripheral circuit CBA corresponding to each other are electrically connected, and the support substrate SS and the semiconductor substrate SB are bonded.

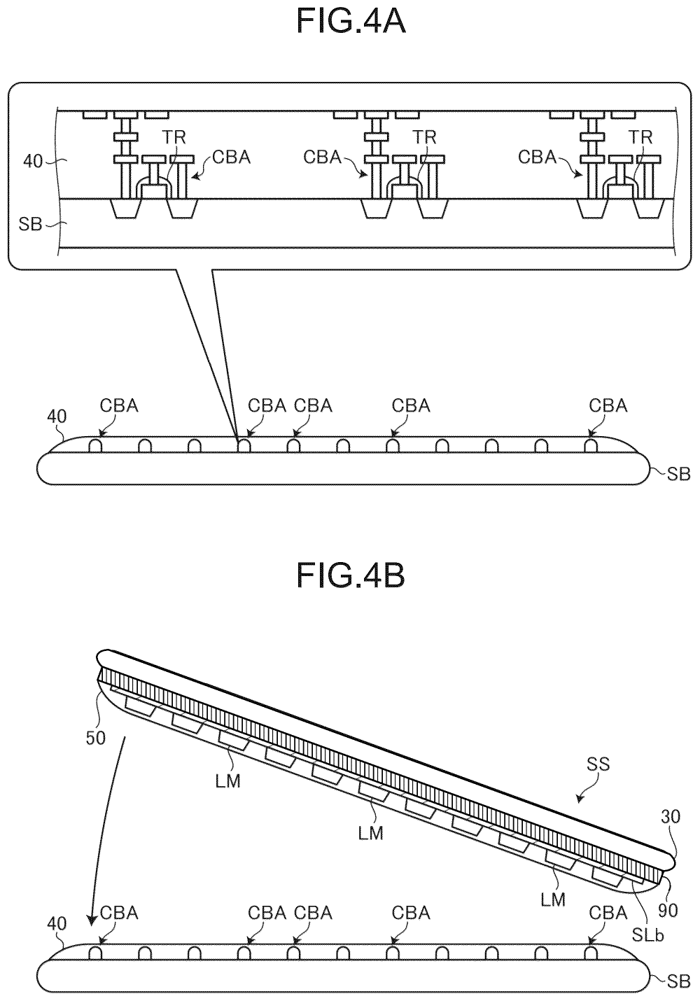

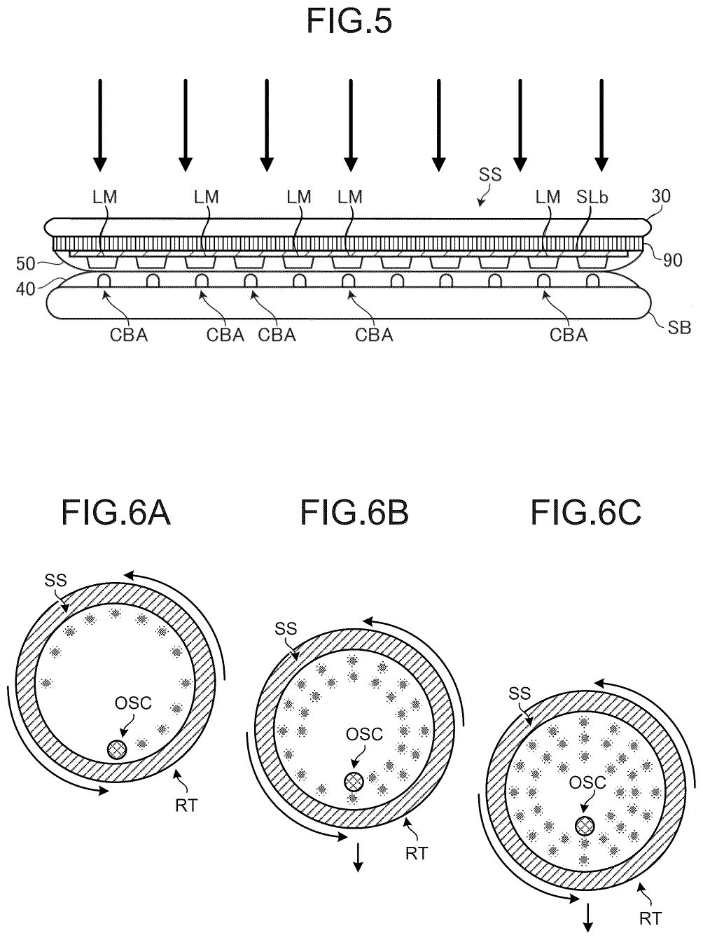

As illustrated in FIG. 5, a bonded material of the support substrate SS and the semiconductor substrate SB is irradiated with laser light having a wavelength of, for example, 9 μm or more and 10 μm or less from the support substrate SS side. As the laser light, for example, a carbon dioxide (CO₂) laser having a wavelength of 9.6 μm can be used. However, the wavelength of the laser light may be, for example, 9.25 μm, 10.6 μm, or the like. In addition, it is preferable to irradiate the laser light in a pulse shape. As a result, the entire surface of the support substrate SS can be irradiated with laser light.

As illustrated in the top views of FIGS. 6A to 6C, when the entire surface of the support substrate SS is irradiated with the laser light by the pulse laser, for example, a bonded material of the support substrate SS and the semiconductor substrate SB is placed on a stage RT that can be rotationally driven and horizontally driven, and the laser light can be sequentially applied in a pulse shape from a laser oscillator OSC while the stage RT is rotated.

That is, every time the stage RT is rotated once to irradiate the support substrate SS with the laser light in a circumferential shape, the stage RT is moved in the horizontal direction to deviate the irradiation position, and then the stage RT is further rotated, so that the entire surface of the support substrate SS can be irradiated with the laser light in a concentric shape.

At this time, as in the examples of FIGS. 6A to 6C, laser light may be applied in a concentric shape from the outer peripheral side toward the center of the support substrate SS, or laser light may be applied in a concentric shape from the center toward the outer peripheral side of the support substrate SS regardless of the examples of FIGS. 6A to 6C.

Note that the pitch of the irradiation positions of the laser light can be, for example, an interval of several tens μm, and the pulse frequency can be, for example, 10 kHz or more and 100 kHz or less.

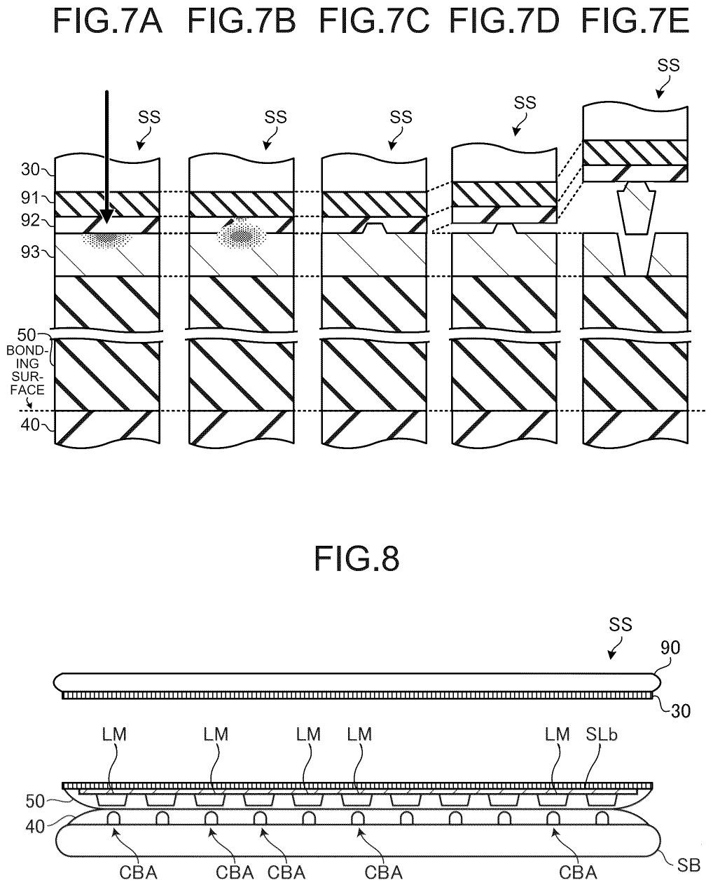

As described above, the support substrate SS is irradiated with laser light, the polysilicon layer 93 is thermally expanded in the above-described multilayer structure body 90 formed on the semiconductor substrate 30, and the polysilicon layer 93 and the insulating layer 92 are cleaved. This state is illustrated in FIGS. 7A to 7E.

As illustrated in FIG. 7A, by the irradiation with the laser light, the phosphorus-doped polysilicon layer 93 with a higher absorption rate of the laser light than the insulating layer 92 and the like absorbs the laser light and generates heat.

As illustrated in FIG. 7B, the insulating layer 92 also slightly generates heat by the irradiation of the laser light, but the heat generation amount of the insulating layer 92 is lower than that of the polysilicon layer 93. In addition, as described above, the thermal conductivity of the insulating layer 92 is equal to or less than 1/10 of that of the polysilicon layer 93. Therefore, the insulating layer 92 can function as a heat insulating layer that prevents the heat from the polysilicon layer 93 from being transferred to the semiconductor substrate 30.

Note that, when the insulating layer 92 functions as a heat insulating layer, the insulating layer 92 preferably has a layer thickness of, for example, 20 nm or more and 50 nm or less as described above. When the insulating layer 92 is too thick, the insulating layer 92 itself serves as a heat source, the heat insulating effect of the insulating layer 92 is weakened, and heat may be transferred to the semiconductor substrate 30. When heat is transferred to the semiconductor substrate 30, the semiconductor substrate 30 itself is thermally expanded, and it is concerned that damage such as lattice defects occurs in the crystal of the semiconductor substrate 30.

Meanwhile, when the insulating layer 92 is not provided on the support substrate SS, the heat of the polysilicon layer 93 is transferred to the semiconductor substrate 30 and dissipated, and thus stress described below generated by thermal expansion of the polysilicon layer 93 is dispersed, whereby it becomes difficult to separate (peel off, debond, lift off) the support substrate SS.

As illustrated in FIG. 7C, the polysilicon layer 93 is thermally expanded. As a result, stress is generated between the polysilicon layer 93 and the insulating layer 92.

As illustrated in FIG. 7D, the insulating layer 92 is pushed up by the stress of the thermally expanded polysilicon layer 93, and the interface between the polysilicon layer 93 and the insulating layer 92 is cleaved.

As illustrated in FIG. 7E, due to the cleavage occurring at the interface between the polysilicon layer 93 and the insulating layer 92, the support substrate SS is separated in a form that the insulating layers 92 and 91 are associated with the semiconductor substrate 30 side. At this time, a thermally expanded portion of the polysilicon layer 93 is associated with the insulating layer 92 and is separated together with the insulating layers 92 and 91 and the like.

As described above, the polysilicon layer 93 and the insulating layer 92 are cleaved using the thermal expansion of the polysilicon layer 93, and thus the support substrate SS can be separated at a relatively low temperature. Therefore, the support substrate SS is removed without spraying or melting a member serving as a starting point of cleavage such as the polysilicon layer 93 and the insulating layer 92 or causing a chemical change in the member.

Note that, as described above, when the entire surface of the support substrate SS is irradiated with the laser light in a pulse shape, the protrusion 931 of the polysilicon layer 93 may be irradiated with the laser light. In this case, the tip portion of the protrusion 931 connected to the semiconductor substrate 30 generates heat, and it is concerned that the heat is transferred to the semiconductor substrate 30. However, as described above, the phosphorus concentration of the protrusion 931 is lowered to be lower than that of the main body portion of the polysilicon layer 93, the amount of heat generation of the protrusion 931 can be prevented, and damage to the semiconductor substrate 30 due to heat transfer from the protrusion 931 can be prevented.

As illustrated in FIG. 8, the support substrate SS that has become the semiconductor substrate 30 including only a part of the multilayer structure body 90 such as the insulating layers 92 and 91 is separated, so that the peripheral circuit CBA that includes the transistor TR and the like formed on the semiconductor substrate SB and the stacked body LM that is bonded to the upper portion of the peripheral circuit CBA via the insulating layers 40 and 50 and includes the pillars PL and the like remain on the semiconductor substrate SB side.

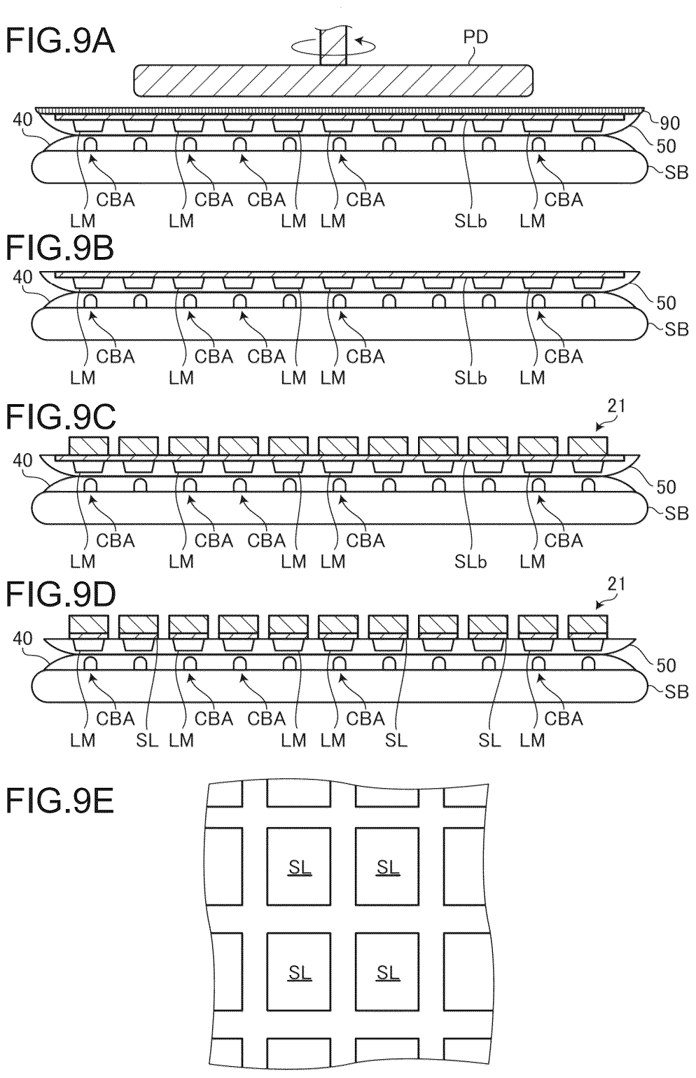

As illustrated in FIG. 9A, the multilayer structure body 90 remaining on the conductive layer SLb side of the stacked body LM bonded on the semiconductor substrate SB is ground and removed using a polishing pad PD by chemical mechanical polishing (CMP) or the like.

As illustrated in FIG. 9B, the multilayer structure body 90 is ground and removed, so that the conductive layer SLb is exposed on the upper surface of the semiconductor substrate SB.

As illustrated in FIG. 9C, the resist pattern 21 having a pattern in accordance with the disposition of the individual stacked body LM is formed on the conductive layer SLb.

As illustrated in FIG. 9D, etching processing is performed on the conductive layer SLb via the resist pattern 21 to form a pattern of the plurality of source lines SL separated for each stacked body LM.

As illustrated in the top view of FIG. 9E, for example, in accordance with the arrangement of the plurality of stacked bodies LM arranged in a grid shape in the plane of the semiconductor substrate SB, the source line SL is also formed, for example, in a pattern of a grid shape.

The source lines SL are formed in a plurality of patterns, and then the resist pattern 21 is removed by ashing processing using oxygen plasma or the like.

Thereafter, the electrode film EL connected to the source line SL via the plug PG formed in the insulating layer 60 is formed, and the semiconductor substrate SB is singulated so as to include at least one stacked body LM, whereby the semiconductor device 1 of the embodiment is manufactured.

Meanwhile, the support substrate SS separated from the semiconductor substrate SB is subjected to regeneration processing described below and reused as the support substrate SS used for manufacturing the new semiconductor device 1.

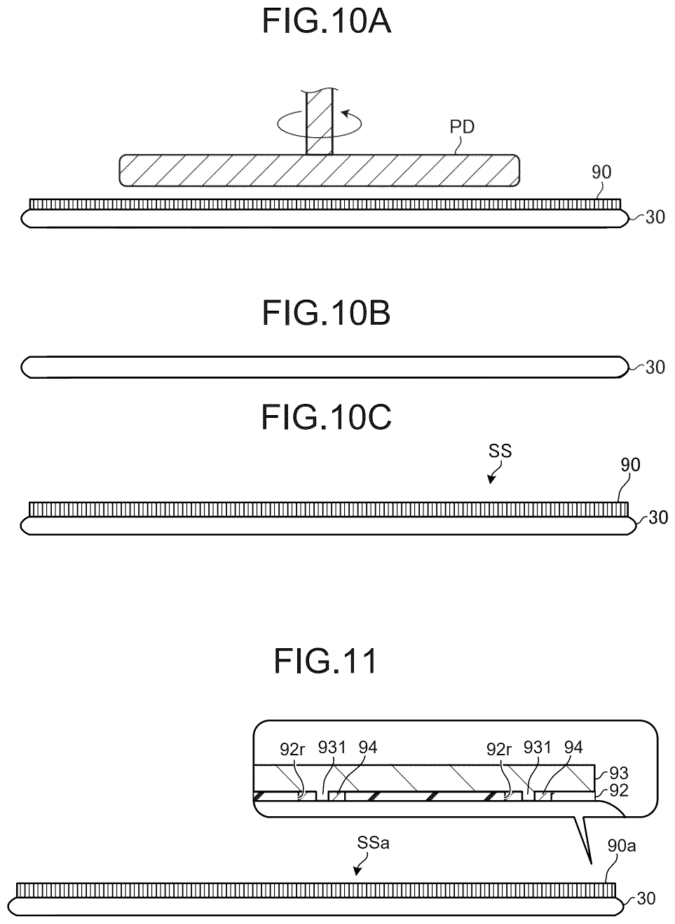

FIGS. 10A to 10C are cross-sectional views illustrating a part of a procedure of regeneration processing of the support substrate SS according to the embodiment.

As illustrated in FIG. 10A, the multilayer structure body 90 remaining on the support substrate SS side due to cleavage is ground and removed using the polishing pad PD. The multilayer structure body 90 may be removed by wet etching or the like.

As illustrated in FIG. 10B, the multilayer structure body 90 is ground and removed to obtain the semiconductor substrate 30 in a substantially initial state.

Thereafter, the processing illustrated in FIG. 2A is performed on the semiconductor substrate 30.

That is, after the semiconductor substrate 30 is cleaned as illustrated in FIG. 10C, both surfaces of the semiconductor substrate 30 are covered, for example, with the insulating layer 91. In addition, the insulating layer 92 and the phosphorus-doped polysilicon layer 93 are formed in this order from the semiconductor substrate 30 side on the semiconductor substrate 30.

As described above, the support substrate SS is regenerated from the used semiconductor substrate 30. Note that the regeneration processing of the support substrate SS illustrated in FIGS. 10A to 10C may also be included in the method of manufacturing the support substrate SS.

### Overview

A semiconductor device such as a three-dimensional nonvolatile memory may be manufactured by, for example, forming a stacked body including a plurality of pillars on a support substrate and bonding the stacked body to a semiconductor substrate on which a peripheral circuit is separately formed. The support substrate is bonded to the semiconductor substrate, then is separated, and is repeatedly reused.

The support substrate is separated by thermally expanding the semiconductor substrate configuring the support substrate, for example, by irradiation with laser light or the like and cleaving the surface of the semiconductor substrate with other members. However, when the support substrate is separated using thermal expansion of the semiconductor substrate itself, damage such as lattice defects occurs in the thermally expanded semiconductor substrate. In addition, the thermally expanded portion of the semiconductor substrate may remain on the insulating layer side covering the peripheral circuit or the like, and damage such as unevenness further occurs on the surface of the semiconductor substrate.

When damage such as lattice defects and irregularities occurs in the semiconductor substrate, a damaged portion of the semiconductor substrate has to be removed during reproduction of the support substrate. As a result, the semiconductor substrate becomes thin every time the reproduction is repeated, and the number of times the support substrate can be reproduced decreases.

The support substrate SS according to the embodiment includes the insulating layer 92 disposed above the semiconductor substrate 30 and the polysilicon layer 93 which is disposed above the insulating layer 92 and doped with phosphorus.

As described above, the phosphorus-doped polysilicon layer 93 has a property of absorbing laser light and serves as a starting point for causing cleavage in the multilayer structure body 90. The insulating layer 92 is less likely to absorb laser light than the polysilicon layer 93 and prevents heat generated in the polysilicon layer 93 from being transferred to the semiconductor substrate 30. As a result, damage to the semiconductor substrate 30 can be prevented when the support substrate SS is separated.

The support substrate SS of the embodiment includes the phosphorus-doped protrusion 931 that extends in the insulating layer 92 and connects the main body portion of the polysilicon layer 93 and the semiconductor substrate 30. As a result, in the plasma processing when the partial configuration of the semiconductor device 1 is formed on the support substrate SS, it is possible to prevent the occurrence of arcing due to charging of the insulating layer 50 and the like.

According to the support substrate SS of the embodiment, the polysilicon layer 93 has a phosphorus concentration of 1.5×10²⁰ atom/cm³ or more and more preferably 3.0×10²⁰ atom/cm³ or more. As a result, in the polysilicon layer 93, the absorption rate of light with a wavelength of 9 μm or more and 10 μm or less can be increased.

According to the support substrate SS of the embodiment, the protrusion 931 of the polysilicon layer 93 has a phosphorus concentration lower than that of the main body portion of the polysilicon layer 93. As a result, for example, when the laser light is irradiated in a pulse shape, even if the laser light hits the protrusion 931, heat generation of the protrusion 931 can be prevented, and heat transfer from the protrusion 931 to the semiconductor substrate 30 is prevented. Therefore, damage to the semiconductor substrate 30 can be further prevented.

According to the support substrate SS of the embodiment, the thickness of the insulating layer 92 is 20 nm or more and 50 nm or less. As described above, the thickness of the insulating layer 92 is appropriately adjusted, so that the insulating layer 92 itself is prevented from becoming a heat source, and heat transfer to the semiconductor substrate 30 is prevented by the heat insulating effect of the insulating layer 92, and damage to the semiconductor substrate 30 is prevented.

With respect to the support substrate SS of the embodiment, the thickness of the main body portion of the polysilicon layer 93 is 100 nm or more and 300 nm or less. As described above, the polysilicon layer 93 is formed to be sufficiently thick with respect to the insulating layer 92, so that stress can be generated by thermal expansion of the polysilicon layer 93, and the interface with the insulating layer 92 can be cleaved.

With respect to the support substrate SS of the embodiment, the protrusions 931 of the polysilicon layer 93 are arranged at the outer edge portions of the plurality of semiconductor devices 1 so as to surround the central portions of the plurality of semiconductor devices 1 formed on the support substrate SS when viewed from the stacking direction of the insulating layer 92, the main body portion of the polysilicon layer 93, and the insulating layer 50.

As a result, in the plasma processing when the semiconductor device 1 is formed, it is possible to further prevent the occurrence of arcing due to charging of the insulating layer 50 and the like.

### Modification

Next, a support substrate SSa according to a modification of the embodiment is described with reference to FIGS. 11 to 13E. The support substrate SSa of the modification is different from that of the above-described embodiment in that a polysilicon layer 932 is further provided around the protrusion 931 of the polysilicon layer 93.

FIG. 11 is a cross-sectional view illustrating an example of a configuration of the support substrate SSa according to the modification of the embodiment. Note that, in the following drawings, the same configurations as those of the above-described embodiment are denoted by the same reference numerals, and the description thereof may be omitted.

As illustrated in FIG. 11, the support substrate SSa of the modification has a configuration in which a multilayer structure body 90a is formed on the semiconductor substrate 30. The multilayer structure body 90a includes a polysilicon layer 94 in addition to the insulating layer 92 and the polysilicon layer 93 of the above-described embodiment.

Note that the support substrate SSa may include an insulating layer 91 such as a silicon nitride layer that covers both surfaces of the semiconductor substrate 30, similarly to the above-described embodiment. That is, the multilayer structure body 90a of the modification may further include the insulating layer 91.

The polysilicon layer 94 is provided on the sidewall of the recess 92r that penetrates the insulating layer 92 and reaches the semiconductor substrate 30, and covers the periphery of the protrusion 931 of the polysilicon layer 93. At this time, the volume of the polysilicon layer 94 is larger than the volume of the protrusion 931.

In addition, as described above, the phosphorus concentration of the main body portion of the polysilicon layer 93 is, for example, 1.5×10²⁰ atom/cm³ or more and more preferably 3.0×10²⁰ atom/cm³ or more, and the phosphorus concentration of the protrusion 931 is equal to or less than the phosphorus concentration of the polysilicon layer 93, whereby the polysilicon layer 94 has a phosphorus concentration lower than these, and more preferably, the polysilicon layer 94 is a non-doped polysilicon layer.

As a result, the polysilicon layer 94 has a lower absorption rate of laser light than the protrusion 931 of the polysilicon layer 93 and has a thermal conductivity equal to or higher than that of the semiconductor substrate 30. Therefore, even when laser light strikes the protrusion 931 of the polysilicon layer 93 at the time of separating the support substrate SSa, the polysilicon layer 94 can function as a heat absorbing layer, and heat generated in the protrusion 931 can be absorbed by the polysilicon layer 94. Therefore, damage to the semiconductor substrate 30 is further prevented.

The support substrate SSa can be manufactured, for example, as follows.

The insulating layer 92 is formed on the semiconductor substrate 30, and the recess 92r penetrating the insulating layer 92 is further formed. Next, when the source gas of the polysilicon layer is supplied to the insulating layer 92, the sidewall of the recess 92r of the insulating layer 92 and the upper surface of the insulating layer 92 are initially covered with the polysilicon layer. In addition, the polysilicon layer gradually increases in thickness toward the central portion of the recess 92r, and the recess 92r is filled with the polysilicon layer.

At this time, initially, the polysilicon layer 94 is formed on the sidewall of the recess 92r of the insulating layer 92 with or without doping phosphorus at a low concentration. When the central portion in the recess 92r is filled, the phosphorus concentration is increased to form the protrusion 931 of the polysilicon layer 93. In this case, after the non-doped polysilicon layer 94 is formed using, for example, SiH₄ gas, the protrusion 931 that is a phosphorus-doped polysilicon layer is formed using a mixed gas obtained by adding Si₂H₆ gas, PH₃ gas, or the like to SiH₄ gas.

Alternatively, after the non-doped polysilicon layer 94 is formed, the portion to be the protrusion 931 can be doped with phosphorus by ion implantation or the like. In this case, a position other than the position corresponding to the protrusion 931 is masked so that ion implantation with phosphorus can be performed.

In either method, since phosphorus is diffused by the annealing treatment in the middle of manufacturing, the phosphorus concentration of the polysilicon layer 94 and the protrusion 931 may have a concentration gradient.

Thereafter, the polysilicon layer 94 and the like having a low phosphorus concentration formed on the insulating layer 92 are removed, and the polysilicon layer 93 doped with phosphorus of a predetermined concentration is formed again.

As described above, the support substrate SSa of the modification is manufactured.

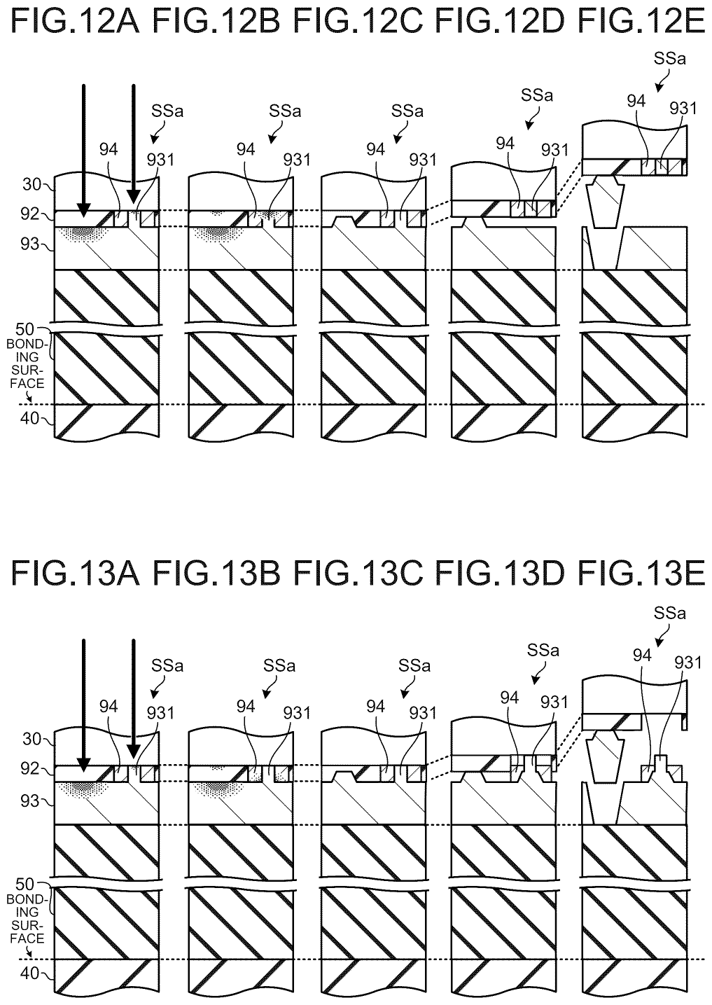

Here, depending on the phosphorus concentration of the protrusion 931 in the polysilicon layer 93, the state of cleavage at the time of separating the support substrate SSa may be different. Examples thereof are illustrated in FIGS. 12A to 13E.

FIGS. 12A to 12E are cross-sectional views schematically illustrating an example of a state in which the support substrate SSa according to the modification of the embodiment is separated. More specifically, FIGS. 12A to 12E illustrate examples in which the phosphorus concentration of the protrusion 931 is in the same level as the phosphorus concentration of the main body portion of the polysilicon layer 93.

As illustrated in FIG. 12A, by the irradiation with the laser light, the phosphorus-doped polysilicon layer 93 with a higher absorption rate of the laser light than the insulating layer 92 and the like absorbs the laser light and generates heat. At this time, when the protrusion 931 of the polysilicon layer 93 is also irradiated with the laser light, the protrusion 931 also absorbs the laser light and generates heat.

As illustrated in FIG. 12B, in a portion where the insulating layer 92 is interposed between the polysilicon layer 93 and the semiconductor substrate 30, the insulating layer 92 functions as a heat insulating layer, and heat from the polysilicon layer 93 is prevented from being transferred to the semiconductor substrate 30. Meanwhile, the protrusion 931 of the polysilicon layer 93 is in direct contact with the semiconductor substrate 30. However, the polysilicon layer 94 having a low phosphorus concentration and functioning as a heat absorbing layer is disposed around the protrusion 931. Therefore, the heat of the protrusion 931 is absorbed into the polysilicon layer 94 and is prevented from being transferred to the semiconductor substrate 30.

At this time, since the volume of the polysilicon layer 94 is larger than the volume of the protrusion 931, the heat from the protrusion 931 can be sufficiently absorbed.

As illustrated in FIG. 12C, the portion of the polysilicon layer 93 irradiated with the laser light is thermally expanded. As a result, stress is generated between the polysilicon layer 93 and the insulating layer 92.

As illustrated in FIG. 12D, the insulating layer 92 is pushed up by the stress of the thermally expanded polysilicon layer 93, and the interface between the polysilicon layer 93 and the insulating layer 92 is cleaved. At this time, the protrusion 931 that generates heat by being irradiated with the laser light and the polysilicon layer 94 that has absorbed the heat are cleaved from the main body portion of the polysilicon layer 93 together with the insulating layer 92 in association with the semiconductor substrate 30.

As illustrated in FIG. 12E, due to the cleavage occurring at the interface between the polysilicon layer 93 and the insulating layer 92, the support substrate SSa is separated in a form that the insulating layer 92 is associated with the semiconductor substrate 30 side. At this time, the thermally expanded portion of the main body portion of the polysilicon layer 93, the protrusion 931 of the polysilicon layer 93, and the polysilicon layer 94 are associated with the insulating layer 92 and separated together with the insulating layer 92 and the like.

FIGS. 13A to 13E are cross-sectional views schematically illustrating another example of a state in which the support substrate SSa according to the modification of the embodiment is separated. More specifically, FIGS. 13A to 13E illustrate examples in which the phosphorus concentration of the protrusion 931 is lower than the phosphorus concentration of the main body portion of the polysilicon layer 93.

As illustrated in FIG. 13A, by the irradiation with the laser light, the phosphorus-doped polysilicon layer 93 with a higher absorption rate of the laser light than the insulating layer 92 and the like absorbs the laser light and generates heat. At this time, when the protrusion 931 of the polysilicon layer 93 is also irradiated with the laser light, the protrusion 931 also absorbs the laser light and generates heat. However, the amount of heat generated by the protrusion 931 with a low phosphorus concentration is smaller than that in the examples of FIGS. 12A to 12E.

As illustrated in FIG. 13B, in a portion where the insulating layer 92 is interposed between the polysilicon layer 93 and the semiconductor substrate 30, the insulating layer 92 functions as a heat insulating layer, and heat from the polysilicon layer 93 is prevented from being transferred to the semiconductor substrate 30. Meanwhile, since the protrusion 931 of the polysilicon layer 93 has a higher thermal conductivity than the polysilicon layer 93, a part of the heat of the protrusion 931 is transferred to the polysilicon layer 93, and the other part is absorbed into the polysilicon layer 94. As a result, heat transfer from the protrusion 931 to the semiconductor substrate 30 is further prevented.

As illustrated in FIG. 13C, the portion of the polysilicon layer 93 irradiated with the laser light is thermally expanded. As a result, stress is generated between the polysilicon layer 93 and the insulating layer 92.

As illustrated in FIG. 13D, the insulating layer 92 is pushed up by the stress of the thermally expanded polysilicon layer 93, and the interface between the polysilicon layer 93 and the insulating layer 92 is cleaved. In addition, in the main body portion of the polysilicon layer 93, a portion to which heat from the protrusion 931 is transferred is also thermally expanded, and the protrusion 931 is pushed upward. At this time, the polysilicon layer 94 that has absorbed the heat of the protrusion 931 is associated with the main body portion of the polysilicon layer 93.

As illustrated in FIG. 13E, due to the cleavage occurring at the interface between the polysilicon layer 93 and the insulating layer 92, the support substrate SSa is separated in a form that the insulating layer 92 is associated with the semiconductor substrate 30 side. At this time, a thermally expanded portion of the main body portion of the polysilicon layer 93 is associated with the insulating layer 92 and is separated together with the insulating layers 92 and the like. The protrusion 931 of the polysilicon layer 93 and the polysilicon layer 94 remain on the semiconductor substrate SB side including the insulating layer 50 and the like.

According to the support substrate SSa of the modification, the sidewall of the protrusion 931 of the polysilicon layer 93 extending in the insulating layer 92 is covered, and the polysilicon layer 94 with a phosphorus concentration lower than that of the polysilicon layer 93 is provided. As a result, even when the laser light strikes and the protrusion 931 generates heat, the heat of the protrusion 931 can be absorbed by the polysilicon layer 94. Therefore, damage to the semiconductor substrate 30 can be further prevented.

In addition, according to the support substrate SSa of the modification, other effects similar to those of the support substrate SS of the above-described embodiment are obtained.

### Examples

Hereinafter, examples are described in detail with reference to the drawings. In the examples, a measurement method and a measurement result of an absorption rate of light of each wavelength in a polysilicon layer functioning as a thermal expansion layer are described.

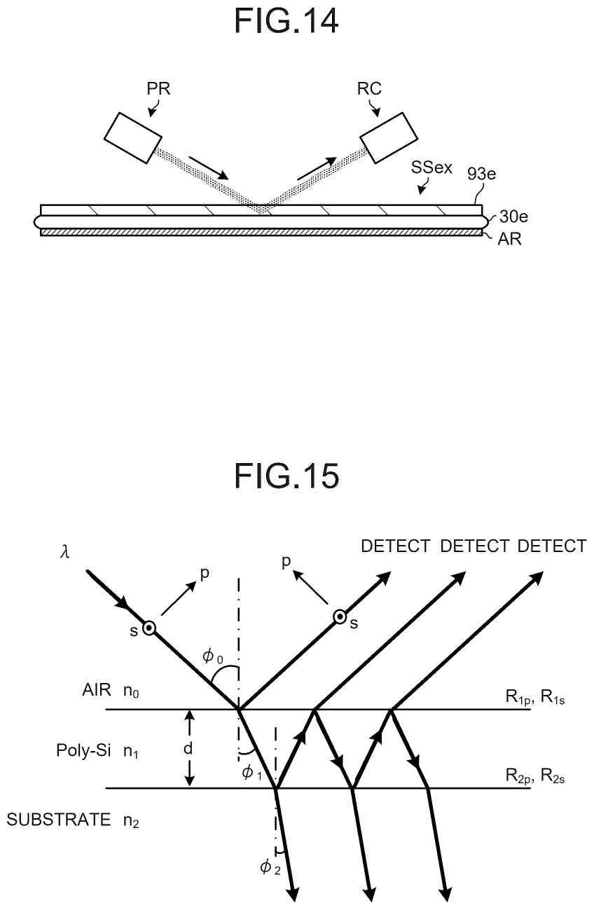

FIG. 14 is a diagram schematically illustrating a measurement substrate SSex and a method of measuring an absorption rate according to the example.

As illustrated in FIG. 14, the measurement substrate SSex is a semiconductor substrate 30e in which an antireflection layer AR is formed on the back surface and a polysilicon layer 93e or the like as an absorption rate measurement target is formed on the front surface.

Light is obliquely incident on the measurement substrate SSex from the light projector PR, and light reflected from the measurement target such as the polysilicon layer 93e is detected by a light receiver RC.

The wavelength of the light applied from the light projector PR can be changed in a range of, for example, 3.0 μm to 11 μm. The light that is reflected on the upper surface, the lower surface, and the like of the polysilicon layer 93e in a multiple manner and finally reflected toward the light receiver RC side is detected in the light receiver RC. At this time, light is caused to be obliquely incident on the measurement substrate SSex, so that the light due to multiple reflection can be decomposed and detected.

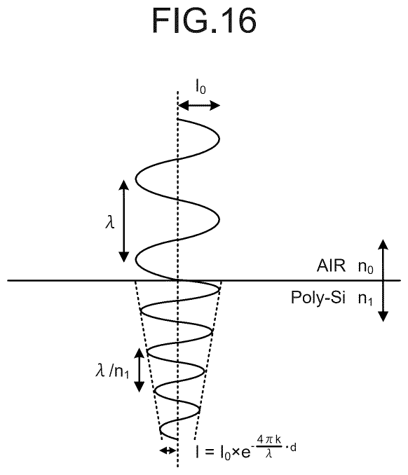

FIGS. 15 and 16 are diagrams schematically illustrating the method of calculating the absorption rate of the polysilicon layer 93e in the measurement substrate SSex according to the example.

As illustrated in FIG. 15, light with a wavelength λ is obliquely incident on the measurement substrate SSex from the light projector PR. The incident angle at this time is an angle φ₀ with respect to a perpendicular drawn on the upper surface of the polysilicon layer 93e on the measurement substrate SSex.

A part of the light reaching the polysilicon layer 93e from the light projector PR is reflected on the upper surface of the polysilicon layer 93e and detected by the light receiver RC. The incident light from the projector PR and the reflected light from the polysilicon layer 93e each include a p-polarization component and an s-polarization component.

The p-polarization component is a polarization component parallel to the incident surface from the projector PR, and the s-polarization component is a polarization component perpendicular to the incident surface of the light from the projector PR. The light incident surface is a surface including both incident light from the light projector PR and reflected light from the polysilicon layer 93e. The p-polarization component and the s-polarization component affect a reflectance of the light with the wavelength λ in the polysilicon layer 93e.

Another part of the light reaching the polysilicon layer 93e from the light projector PR is incident into the polysilicon layer 93e at an angle φ₁ with respect to the layer thickness direction of the polysilicon layer 93e. A part of the light incident into the polysilicon layer 93e is reflected on the lower surface of the polysilicon layer 93e, and another part is transmitted to the semiconductor substrate 30e side at an angle φ₂ with respect to the layer thickness direction of the polysilicon layer 93e.

A part of the light reflected on the lower surface of the polysilicon layer 93e is transmitted through the upper surface of the polysilicon layer 93e and detected by the light receiver RC. Another part of the light reflected on the lower surface of the polysilicon layer 93e is further reflected on the upper surface of the polysilicon layer 93e. A part of the light reflected on the upper surface of the polysilicon layer 93e is reflected on the lower surface of the polysilicon layer 93e, and another part is transmitted to the semiconductor substrate 30e side.

As described above, the light that is reflected on the surface of the polysilicon layer 93e and the light that is reflected in the polysilicon layer 93e in a multiple manner and finally transmitted to the light receiver RC side are detected by the light receiver RC. In addition, an n/k value is obtained using Formulas (1) to (8) based on the information on the light detected by the light receiver RC. n is a refractive index of the polysilicon layer 93e, and k is an extinction coefficient of the polysilicon layer 93e.

Intensity reflectance Rp of p-polarization component=rₚ·rₚ . . . (1)

Intensity reflectance Rs of s-polarization component=rₛ·rₛ . . . (2)
rₚ: Amplitude reflectance of p-polarization component
rₛ: Amplitude reflectance of s-polarization component

rₚ=(r₁ₚ+r₂ₚ×e^{-iδ})/(1+r₁ₚ·r₂ₚ×e^{-iδ}) . . . (3)

rₛ=(r₁ₛ+r₂ₛ×e^{-iδ})/(1+r₁ₛ·r₂ₛ×e^{-iδ}) . . . (4)

δ=(4π/λ)nd·cosφ₁ . . . (5)
i: Imaginary number
δ: Phase difference when light with wavelength λ reciprocates once in polysilicon layer 93e
n: Refractive index of polysilicon layer 93e
d: Layer thickness of polysilicon layer 93e

Reflection Fresnel coefficient rᵢₚ of p-polarization component=

(nᵢ·cosφᵢ₋₁−nᵢ₋₁·cosφᵢ)/(nᵢ·cosφᵢ₋₁+nᵢ₋₁·cosφᵢ) . . . (6)

Reflection Fresnel coefficient rᵢₛ of s-polarization component=

(nᵢ₋₁·cosφᵢ−nᵢ·cosφᵢ₋₁)/(nᵢ₋₁·cosφᵢ+nᵢ·cosφᵢ₋₁) . . . (7)
nᵢ: complex refractive index of polysilicon layer 93e

n=nᵢ−ik . . . (8)

Here, the refractive index and the layer thickness of the polysilicon layer 93e are known. Therefore, the n/k value is obtained by Formulas (1) to (8).

As illustrated in FIG. 16, when the light with the wavelength λ is incident on the polysilicon layer 93e at an intensity I₀, in the polysilicon layer 93e, the wavelength of the light becomes a wavelength λ/n₁ according to a refractive index n₁ of the polysilicon layer 93e, and an intensity I of the light transmitted through the polysilicon layer 93e with a layer thickness d is expressed by Formula (9).

I=I₀×exp((−4πk/λ)·d) . . . (9)

In addition, an absorption rate A of light having the wavelength λ in the polysilicon layer 93e can be obtained from Formula (10).

Absorption rate A=(I₀−I)/I₀=1−e^{-αx} . . . (10)
α: Absorption coefficient

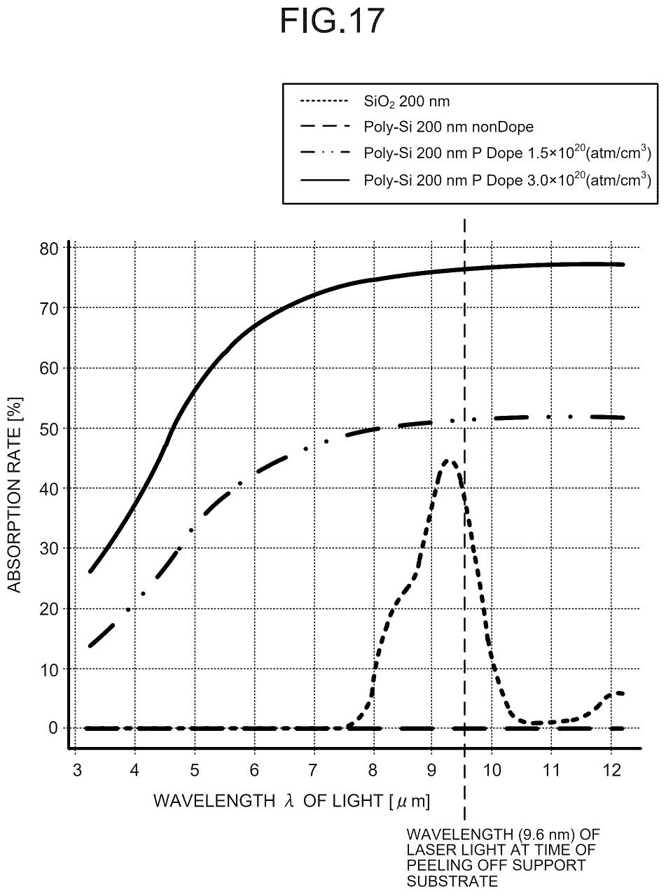

FIG. 17 is a graph illustrating an absorption rate of the polysilicon layer 93e in the measurement substrate SSex according to the example. In the graph of FIG. 17, the horizontal axis represents the wavelength λ (nm) of the light applied to the polysilicon layer 93e, and the vertical axis represents the absorption rate (%) of the light with each wavelength λ in the polysilicon layer 93e.

In addition, as the polysilicon layer 93e illustrated in FIG. 14, a non-doped polysilicon layer, a polysilicon layer doped with phosphorus of 1.5×10²⁰ atom/cm³, and a polysilicon layer doped with phosphorus of 3.0×10²⁰ atom/cm³ were used as measurement targets. The thickness of these polysilicon layers was 200 nm. Also, for comparison, the absorptivity of the silicon oxide layer that is used for the insulating layer 92 and the like and has a layer thickness of 200 nm was also measured.

In the graph of FIG. 17, for reference, 9.6 μm, which is the wavelength of the carbon dioxide gas laser light that can be used at the time of separating the support substrate SS of the above-described embodiment, is indicated by a broken line.

As illustrated in FIG. 17, the absorption rate of the light in the silicon oxide layer with a layer thickness of 200 nm was about 45% at a wavelength λ of about 9 μm, and the absorption rate of the light in the non-doped polysilicon layer 93e was consistently 0% over a wavelength of 3.0 μm to 12 μm.

Meanwhile, the result showed that the absorption rate in the phosphorus-doped polysilicon layer 93e increased as the wavelength λ of light increased up to around a wavelength of 7.0 μm, and the amount of increase in the absorption rate also increased as the phosphorus concentration increased.

More specifically, the absorption rate in the polysilicon layer doped with phosphorus of 3.0×10²⁰ atom/cm³ at a wavelength λ of 9 μm or more was 75% or more, and the absorption rate in the polysilicon layer doped with phosphorus of 1.5×10²⁰ atom/cm³ was 50% or more.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A stacked substrate for separating a semiconductor substrate using thermal expansion by laser light, comprising:
the semiconductor substrate;
a first insulating layer disposed above the semiconductor substrate;
a first polysilicon layer that is disposed on the first insulating layer in contact with the first insulating layer, and doped with phosphorus; and
a second polysilicon layer that extends through the first insulating layer in a stacked direction of the first insulating layer and the first polysilicon layer, directly connects the first polysilicon layer and the semiconductor substrate, and is doped with phosphorus.

2. The stacked substrate according to claim 1, wherein
the first polysilicon layer has a phosphorus concentration of 1.5×10²⁰ atom/cm³ or more.

3. The stacked substrate according to claim 1, wherein
the first polysilicon layer has a phosphorus concentration of 3.0×10²⁰ atom/cm³ or more.

4. The stacked substrate according to claim 1, wherein
the second polysilicon layer has a phosphorus concentration lower than a phosphorus concentration of the first polysilicon layer.

5. The stacked substrate according to claim 1, further comprising:
a third polysilicon layer that extends through the first insulating layer in the stacked direction, covers a sidewall of the second polysilicon layer, and has a phosphorus concentration lower than a phosphorus concentration of the first polysilicon layer.

6. The stacked substrate according to claim 5, wherein
the second polysilicon layer has a phosphorus concentration equal to the phosphorus concentration of the first polysilicon layer.

7. The stacked substrate according to claim 5, wherein
the second polysilicon layer has a phosphorus concentration lower than the phosphorus concentration of the first polysilicon layer and higher than the phosphorus concentration of the third polysilicon layer.

8. The stacked substrate according to claim 1, further comprising:
a device layer that includes at least a part of a semiconductor device above the first polysilicon layer.

9. The stacked substrate according to claim 8, wherein
a thickness of the first insulating layer is 20 nm or more and 50 nm or less,
a thickness of the first polysilicon layer is 100 nm or more and 300 nm or less, and
a thickness of the device layer is 500 nm or more.

10. The stacked substrate according to claim 8, wherein
the second polysilicon layer is disposed at an outer edge of the semiconductor device so as to surround a central portion of the semiconductor device when viewed from the stacking direction.

11. A method of manufacturing a semiconductor device, the method comprising:
forming a first insulating layer above a first semiconductor substrate;
forming a recess in the first insulating layer;
forming a first polysilicon layer on the first insulating layer and a second polysilicon layer in the recess and reaches the first semiconductor substrate, the first polysilicon layer and the second polysilicon layer being doped with phosphorus;
forming a device layer that includes at least a part of a semiconductor device above the first polysilicon layer; and
irradiating the first polysilicon layer with laser light, cleaving a portion between the first insulating layer and the first polysilicon layer, and separating the first semiconductor substrate.

12. The method of manufacturing a semiconductor device according to claim 11, wherein
the formation of the device layer includes:
forming a stacked body in which a plurality of conductive layers are stacked apart from each other, above the first polysilicon layer; and
forming a memory pillar that penetrates the stacked body.

13. The method of manufacturing a semiconductor device according to claim 12, further comprising:
before separating the first semiconductor substrate,
forming a peripheral circuit that includes a transistor on a second semiconductor substrate; and
bonding a surface of the first semiconductor substrate on which the device layer is formed and a surface of the second semiconductor substrate on which the peripheral circuit is formed.

14. The method of manufacturing a semiconductor device according to claim 11, wherein
the formation of the first polysilicon layer includes doping phosphorus at a concentration of 1.5×10²⁰ atom/cm³ or more.

15. The method of manufacturing a semiconductor device according to claim 11, wherein
the formation of the first polysilicon layer includes
doping phosphorus at a concentration of 3.0×10²⁰ atom/cm³ or more.

16. The method of manufacturing a semiconductor device according to claim 11, wherein
the formation of the second polysilicon layer includes
doping phosphorus at a concentration lower than a concentration of the first polysilicon layer.

17. The method of manufacturing a semiconductor device according to claim 11, further comprising:
forming a third polysilicon layer that covers a sidewall of the recess and has a phosphorus concentration lower than a phosphorus concentration of the first polysilicon layer.

18. The method of manufacturing a semiconductor device according to claim 17, wherein
the formation of the second polysilicon layer includes
doping phosphorus at a concentration equal to a concentration of the first polysilicon layer.

19. The method of manufacturing a semiconductor device according to claim 17, wherein
the formation of the second polysilicon layer includes
doping phosphorus at a phosphorus concentration lower than the phosphorus concentration of the first polysilicon layer and higher than the phosphorus concentration of the third polysilicon layer.

20. The method of manufacturing a semiconductor device according to claim 11, wherein
the formation of the second polysilicon layer includes
forming the second polysilicon layer at an outer edge of the semiconductor device so as to surround a central portion of the semiconductor device when viewed from a stacking direction of the first insulating layer, the first polysilicon layer, and the device layer.
